(19) United States
(12) Patent Application Publication
(10) Pub. No.: US 2026/0227428 A1
(43) Pub. Date: Aug. 6, 2026

(54) PROBER AND PROBE INSPECTION METHOD

(71) Applicant: Tokyo Seimitsu Co., Ltd., Tokyo (JP)

(72) Inventors: Takekiyo ICHIKAWA, Tokyo (JP); Satoshi UCHIDA, Tokyo (JP); Shingo MITSUZAWA, Tokyo (JP); Shunsuke OTAKE, Tokyo (JP); Kota TERAKAWA, Tokyo (JP)

(21) Appl. No.: 19/146,127

(22) PCT Filed: Dec. 19, 2023
(86) PCT No.: PCT/JP2023/045420

§ 371 Date: Jul. 7, 2025

(30) Foreign Application Priority Data
Jan. 13, 2023 (JP) 2023-003518

(51) Int. Cl. G01R 1/073; G01R 1/067

(52) U.S. Cl. CPC G01R 1/07364; G01R 1/06794; G01R 1/07342

(57) ABSTRACT

Provided is a prober 10 including a plurality of measurement parts 16 and an alignment apparatus 70. Each of the measurement parts 16 is provided with a wafer chuck 50 and a probe card 56. The alignment apparatus 70 is configured to be movable between the measurement parts 16. The alignment apparatus 70 detachably supports the wafer chuck 50 and performs relative alignment of the wafer chuck 50 with respect to the probe card 56. The alignment apparatus 70 further includes a probe position detection camera 82 detecting tip positions of probes 66 and an angle tilting mechanism 76 tilting the wafer chuck 50 and the probe position detection camera 82 integrally to adjust such that the probe card 56 is parallel to the wafer chuck 50. Accordingly, a prober is provided that can detect probes with high accuracy without being affected by the tilt of a probe card and achieve good contact between electrode pads on a wafer and the probes.

### FIELD

The present disclosure relates to a prober and a probe inspection method.

### BACKGROUND

A semiconductor manufacturing process has many steps. In the semiconductor manufacturing process, various inspections are performed in various manufacturing steps in order to assure quality and improve yield. For example, wafer level inspection is performed at a stage in which a plurality of semiconductor chips of semiconductor devices are formed on a semiconductor wafer. The wafer level inspection is an electric inspection to determine whether the semiconductor device of each semiconductor chip operates normally. The method is to connect an electrode pad of the semiconductor device of each semiconductor chip to a test head, supply power and a test signal from the test head, and measure a signal output by the semiconductor device with the test head.

After the wafer level inspection, the wafer is attached to a frame and cut into individual semiconductor chips by a dicer. Out of the cut semiconductor chips, semiconductor chips determined to operate normally are packaged in a next assembly step. The packaged final product is inspected for shipment. On the other hand, chips with faulty operation are excluded from the assembly step.

The wafer level inspection is performed using a prober. The prober brings a probe into contact with an electrode pad. The probe is electrically connected to a terminal of the test head. The test head supplies power and a test signal to each semiconductor chip via the probe. The test head detects an output signal from each semiconductor chip to inspect whether the semiconductor device operates normally.

In the semiconductor manufacturing process, to reduce manufacturing costs, wafers are being made larger and further miniaturized (integrated). As a result, the number of chips formed on a single wafer is very large. Along with that, the time required to inspect a single wafer at the prober is also increasing. Thus, there is a demand for improving inspection throughput.

To improve throughput, multi-probing could be employed. Multi-probing is a method for inspecting a plurality of chips simultaneously by providing many probes. In recent years, the number of chips inspected simultaneously has been increasing more and more, and attempts are being made to inspect all semiconductor chips on a wafer simultaneously. In multi-probing, on the other hand, the tolerance for alignment bringing the electrode pads and the probes into contact with each other tends to be smaller. Thus, there is a demand for improving the positional accuracy of movement in the prober.

As another method for improving throughput, increasing the number of probers could be employed. However, an increase in the number of probers creates the problem of an increase in the installation area of the probers in a manufacturing line. In addition, increasing the number of probers also increases apparatus costs accordingly. Thus, there is a demand for a method for curbing the increase in the installation area or the increase in apparatus costs to improve throughput.

Against this background, for example, Patent Literature 1 proposes a test apparatus (a multistage type prober) including a plurality of measurement parts. This test apparatus is configured such that an alignment apparatus performing relative alignment between a wafer and a probe card can move reciprocally between the measurement parts.

As another viewpoint, to perform accurate inspection using the prober, the probes and the electrode pads on the wafer are required to be in uniform contact with each other. Uniform contact can be achieved by making the probe card and the wafer parallel to each other. However, it may be difficult to maintain the parallelism due to influence such as changes in the volume of the members. Inspection by the prober is performed while a measurement environment is temperature-controlled to high temperatures or low temperatures. Thus, (minute) volume changes (expansion and contraction) can occur in each member due to temperature changes in the measurement environment.

An angle tilting mechanism could be used in order to maintain the parallelism between the probe card and the wafer. For example, the angle tilting mechanism can be installed on the mechanism holding the probe card or the angle tilting mechanism can be provided on the mechanism holding a wafer chuck.

For example, the prober disclosed in Patent Literature 2 includes the angle tilting mechanism on the mechanism holding the wafer chuck. This prober can maintain the parallelism between the probe card and the wafer by checking the degree of tilt of the probe card with an upper part checking camera and tilting the wafer chuck holding the wafer with the tilting mechanism based on the degree of tilt.

### CITATION LIST

### Patent Literature

Patent Literature 1: Japanese Patent Application Laid-open No. 2014-150168.

Patent Literature 2: Japanese Patent Application Laid-open No. 2017-069427.

### SUMMARY

### Technical Problem

The prober disclosed in Patent Literature 2 may be unable to achieve good contact between the electrode pads on the wafer and the probes.

In the prober of Patent Literature 2, when the wafer chuck is tilted, a change in the relative positional relation with the upper part checking camera occurs. This makes it difficult to detect the positional relation between the wafer held by the wafer chuck and the probes with high accuracy.

Meanwhile, the method for installing the angle tilting mechanism on the mechanism holding the probe card also has had problems. In a multistage type prober, the angle tilting mechanism must be provided for each measurement part, which makes the structure complex or is disadvantageous in terms of costs.

An object of the present disclosure is to solve at least one of the problems that the conventional technologies have had. A specific object is to provide a prober and a probe inspection method that can detect probes with high accuracy without being affected by the tilt of a probe card and achieve good contact between electrode pads on a wafer and the probes.

### Solution to Problem

An embodiment of a prober of the present disclosure is a prober including a plurality of measurement parts, each of the measurement parts being provided with a wafer chuck and a probe card, the wafer chuck having a holding surface configured to hold a wafer, the probe card having a plurality of probes on a surface facing the holding surface, and an alignment apparatus configured to be movable between the measurement parts and detachably support the wafer chuck at a measurement part as a movement destination to perform relative alignment of the wafer chuck with respect to the probe card. The alignment apparatus includes a probe position detection camera configured to detect tip positions of the probes at a position facing the probe card, and a tilting mechanism configured to tilt the wafer chuck and the probe position detection camera integrally.

An embodiment of a probe inspection method of the present disclosure is a probe inspection method in a prober including a probe card including a plurality of measurement parts, each of the measurement parts having a wafer chuck having a holding surface configured to hold a wafer and a plurality of probes on a surface facing the holding surface, and an alignment apparatus configured to be movable between the measurement parts and detachably support the wafer chuck at a measurement part as a movement destination to perform relative alignment of the wafer chuck with respect to the probe card. The alignment apparatus includes a probe position detection camera configured to detect tip positions of the probes at a position facing the probe card, and a tilting mechanism that tilts the wafer chuck. The probe inspection method includes a detection step of detecting a tilt angle of the probe card, and a tilt control step of controlling the tilting mechanism based on a detection result of the detection step to tilt the wafer chuck and the probe position detection camera integrally such that the holding surface is parallel to the probe card.

### Advantageous Effects of Invention

The present disclosure can solve at least one of the problems that the conventional technologies have. As a specific example, provided are a prober and a probe inspection method that can detect probes with high accuracy without being affected by the tilt of a probe card and achieve good contact between electrode pads on a wafer and the probes.

### BRIEF DESCRIPTION OF DRAWINGS

FIG. 1 is a perspective view of an overall configuration of a prober according to an embodiment of the present invention.

FIG. 2 is a plan view schematically illustrating an internal structure of the prober illustrated in FIG. 1.

FIG. 3 is a schematic view of a configuration of a measurement unit viewed from the loader side.

FIG. 4 is a schematic view of a configuration of a measurement part.

FIG. 5 is a functional block diagram of a prober controller.

FIG. 6 is a flowchart of a procedure of a probe inspection method.

FIG. 7 is a diagram for illustrating the probe inspection method.

FIG. 8 is a diagram for illustrating cleaning processing using a cleaning plate of the prober.

FIG. 9 is a diagram for illustrating observation in which the observation direction of a probe position detection camera of the prober is directed outside.

### DESCRIPTION OF EMBODIMENTS

A first embodiment of the prober of the present disclosure is a prober including a plurality of measurement parts, each of the measurement parts being provided with a wafer chuck and a probe card, the wafer chuck having a holding surface configured to hold a wafer, the probe card having a plurality of probes on a surface facing the holding surface, and an alignment apparatus configured to be movable between the measurement parts and detachably support the wafer chuck at a measurement part as a movement destination to perform relative alignment of the wafer chuck with respect to the probe card. The alignment apparatus includes a probe position detection camera configured to detect tip positions of the probes at a position facing the probe card, and a tilting mechanism configured to tilt the wafer chuck and the probe position detection camera integrally.

A second embodiment of the prober of the present disclosure is the prober according to the first embodiment, in which the alignment apparatus includes a common support configured to commonly support the wafer chuck and the probe position detection camera, and the tilting mechanism tilts the common support to tilt the wafer chuck and the probe position detection camera integrally.

A third embodiment of the prober of the present disclosure is the prober according to the second embodiment, in which the alignment apparatus includes a moving mechanism configured to relatively move the wafer chuck with respect to the probe card in a direction parallel to the holding surface, and the tilting mechanism is provided between the moving mechanism and the common support.

A fourth embodiment of the prober of the present disclosure is the prober according to any one of the first to third embodiments, further including a detector configured to detect a tilt angle of the probe card, and a controller configured to control the tilting mechanism such that the holding surface is parallel to the probe card based on a detection result of the detector.

A fifth embodiment of the prober of the present disclosure is the prober according to the fourth embodiment, in which the detector detects the tilt angle of the probe card based on a detection result of the probe position detection camera.

A sixth embodiment of the prober of the present disclosure is the prober according to any one of the first to third embodiments, in which the alignment apparatus includes a cleaning plate configured to clean tips of the probes, and the tilting mechanism tilts the cleaning plate integrally with the wafer chuck.

A first embodiment of the probe inspection method of the present disclosure is a probe inspection method in a prober including a probe card including a plurality of measurement parts, each of the measurement parts having a wafer chuck having a holding surface configured to hold a wafer and a plurality of probes on a surface facing the holding surface, and an alignment apparatus configured to be movable between the measurement parts and detachably support the wafer chuck at a measurement part as a movement destination to perform relative alignment of the wafer chuck with respect to the probe card, the alignment apparatus including a probe position detection camera configured to detect tip positions of the probes at a position facing the probe card, and a tilting mechanism configured to tilt the wafer chuck, the probe inspection method including a detection step of detecting a tilt angle of the probe card, and a tilt control step of controlling the tilting mechanism based on a detection result of the detection step to tilt the wafer chuck and the probe position detection camera integrally such that the holding surface is parallel to the probe card.

A second embodiment of the probe inspection method of the present disclosure is the probe inspection method according to the first embodiment of the probe inspection method, in which the detection step includes detecting a tilt angle of the probe card based on a detection result of the probe position detection camera.

Preferred embodiments will be described below in accordance with the accompanying drawings.

### Prober

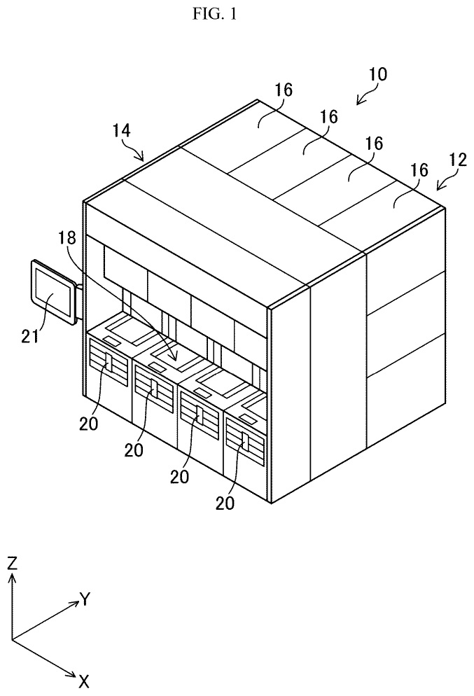

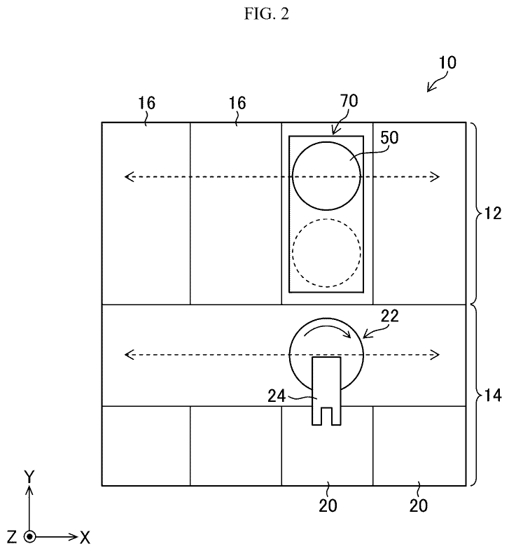

FIG. 1 and FIG. 2 are a perspective view and a plan view, respectively, of an overall configuration of an embodiment of the prober.

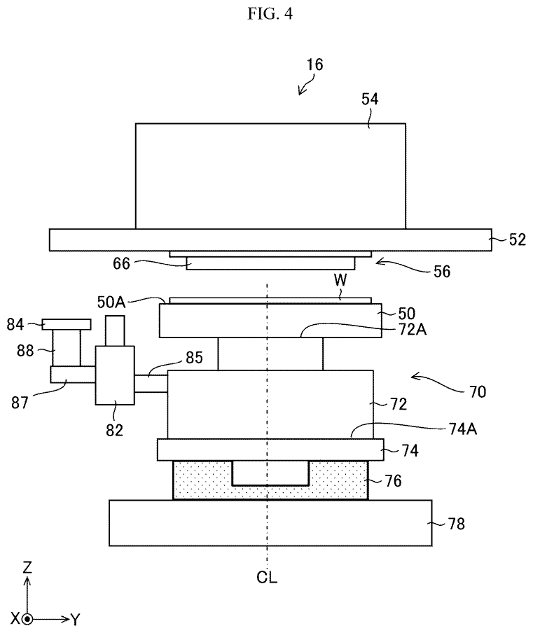

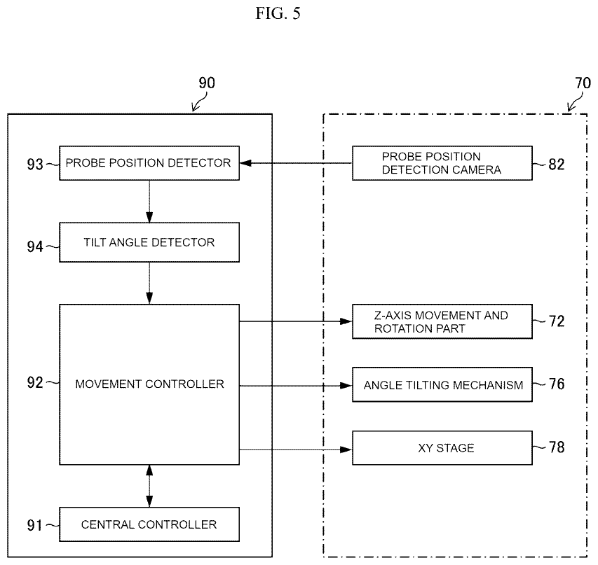

As illustrated in FIG. 1 and FIG. 2, this prober 10 of the embodiment includes a loader 14 and a measurement unit 12. The loader 14 supplies and collects a wafer W to be inspected (refer to FIG. 4). The measurement unit 12 is disposed adjacent to the loader 14. The prober 10 is a multistage type prober in which the measurement unit 12 includes a plurality of measurement parts 16. The loader 14 supplies the wafer W to each of the measurement parts 16. The measurement part 16 performs inspection of the electric characteristics of each semiconductor chip of the supplied wafer W (wafer level inspection). The wafer W inspected by the measurement part 16 is collected by the loader 14. Note that the prober 10 also includes an operating panel 21, a controller 90 (refer to FIG. 5) controlling the parts, and the like.

The loader 14 includes a load port 18 and a transport unit 22. A wafer cassette 20 is placed on the load port 18. The transport unit 22 transports the wafer W between each measurement part 16 and the wafer cassette 20. The transport unit 22 includes a non-illustrated transport unit drive mechanism. The transport unit 22 is configured to be movable in an X-axis direction and a Z-axis direction and is configured to be rotatable in a θ direction (about the Z-axis direction). In addition, the transport unit 22 includes a transport arm 24. The transport arm 24 is configured to be expandable and contractable back and forth and is expanded and contracted by the transport unit drive mechanism. A non-illustrated suction pad is provided on the upper surface of the transport arm 24. The transport arm 24 vacuum sucks the backside of the wafer W with this suction pad to hold the wafer W.

The wafer W inside the wafer cassette 20 is taken out by the transport arm 24 of the transport unit 22. The wafer W is transported to each measurement part 16 of the measurement unit 12 while being held on the upper surface of the transport arm 24. The inspected wafer W having passed through inspection is returned to the wafer cassette 20 from each measurement part 16 through a reverse route.

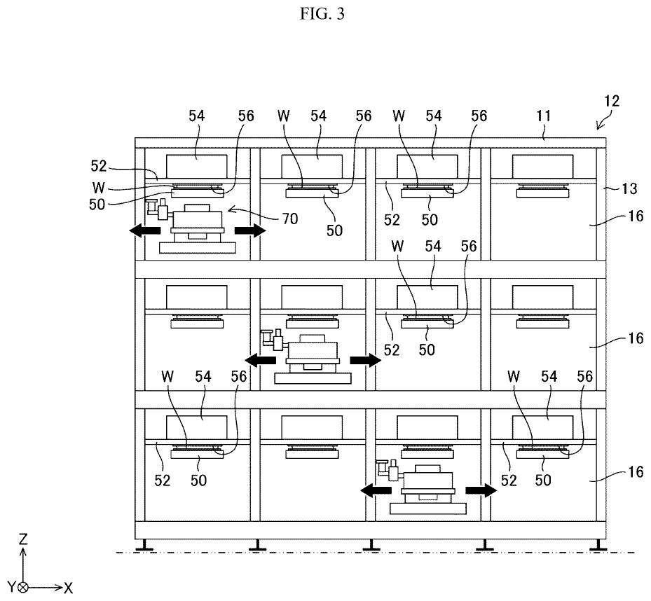

FIG. 3 is a diagram of a configuration of the measurement unit 12 viewed from the loader side.

As illustrated in FIG. 3, the measurement unit 12 has a stacked structure (a multistage structure) in which a plurality of measurement parts 16 are stacked on each other in a multistage manner. The measurement parts 16 are arranged in a two-dimensional manner along the X-axis direction and the Z-axis direction. In this embodiment, four measurement parts 16 in the X-axis direction are stacked on each other in three tiers in the Z direction. Note that all the measurement parts 16 have the same configuration. As described below, each of the measurement parts 16 includes a test head 54, a wafer chuck 50, a probe card 56, and the like.

The measurement unit 12 includes a casing 11. The casing 11 has a grid shape in which a plurality of frames are combined in a grid shape. A plurality of frames 13 are combined to constitute the casing 11. The frames 13 extend in the X-axis direction, a Y-axis direction, and the Z-axis direction to be combined in a grid shape.

An alignment apparatus 70 is provided for each tier. That is, in the present example, the alignment apparatus 70 is provided for each of the three tiers stacked on each other in the Z direction.

The alignment apparatus 70 can move between the measurement parts 16 disposed in each layer (each tier). In other words, the alignment apparatus 70 is shared by the (four in the embodiment) measurement parts 16 disposed in the same layer (tier).

### Measurement Part

Next, a configuration of the measurement part 16 will be described. FIG. 4 is a schematic view of the configuration of the measurement part 16.

As illustrated in FIG. 4, the measurement part 16 includes the wafer chuck 50, a head stage 52, the test head 54, and the probe card 56.

The test head 54 is supported above the head stage 52 by a test head holder. Note that the test head holder is not illustrated. The test head 54 is electrically connected to a probe 66 of the probe card 56. The test head 54 supplies power and a test signal to each semiconductor chip for electric characteristic inspection. The test head 54 detects an output signal from each semiconductor chip to measure whether it operates normally.

The head stage 52 is supported on a frame (not illustrated) that constitutes a part of the casing. The head stage 52 includes a pogo frame mounting part. The pogo frame mounting part is a circular opening. The circular opening corresponds to the planar shape of a pogo frame. Note that the pogo frame and the pogo frame mounting part are not illustrated. How the pogo frame is fixed to the head stage 52 is not limited to the above.

The pogo frame includes a plurality of pogo pins. The pogo pins electrically connect terminals formed on the lower surface of the test head 54 and terminals formed on the upper surface of the probe card 56 to each other.

A ring-shaped sealing member is formed each on the upper surface side and the lower surface side of the outer periphery of the pogo frame. Note that the upper surface side is a surface facing the test head 54, and the lower surface side is a surface facing the probe card 56.

The test head 54, the pogo frame, and the probe card 56 are integrated by a sucker.

That is, the space surrounded by the test head 54, the pogo frame, and the upper surface side sealing member and the space surrounded by the probe card 56, the pogo frame, and the lower surface side sealing member are depressurized and fixed. Note that the sealing member and the sucker are not illustrated.

The probe card 56 includes many probes 66. The probes 66 correspond to electrode pads of respective semiconductor chips of the wafer W. Each of the probes 66 is formed protruding downward from the lower surface of the probe card 56. The lower surface of the probe card 56 faces the wafer chuck 50. The probes 66 are electrically connected to the respective terminals provided on the upper surface of the probe card 56.

Thus, when the test head 54, the pogo frame (not illustrated), and the probe card 56 are integrated, each of the probes 66 is electrically connected to each terminal of the test head 54 via the pogo frame. Note that the probe card 56 of the embodiment includes many probes 66 corresponding to the electrode pads of all the semiconductor chips of the wafer W to be inspected. Each measurement part 16 performs simultaneous inspection on the semiconductor chips on the wafer W. Note that the wafer W is held by the wafer chuck 50 during inspection.

The wafer chuck 50 has a holding surface 50A. The wafer W is held on the upper surface of the holding surface 50A. The holding surface 50A is configured as a plane and sucks and fixes the wafer W by vacuum suction or the like. The wafer chuck 50 is detachably supported on the alignment apparatus 70. The wafer chuck 50 is made movable in the X-axis direction, the Y-axis direction, the Z-axis direction, and the θ direction by the alignment apparatus 70. A ring-shaped sealing member (not illustrated) is provided on the outer periphery of the holding surface 50A.

The space surrounded by the probe card 56, the wafer chuck 50, and the sealing member is depressurized by a non-illustrated sucker. The space is depressurized, and thus the wafer chuck 50 is attracted toward the probe card 56. This brings each probe 66 of the probe card 56 into contact with the electrode pad of each semiconductor chip of the wafer W. When the probe 66 comes into contact with the electrode pad, inspection can be started.

A heating and cooling mechanism (not illustrated) is provided inside the wafer chuck 50. The heating and cooling mechanism adjusts the temperature of the semiconductor chips. Electric characteristics inspections are often performed at −40 to 150° C. The heating and cooling mechanism performs temperature control on a measurement environment such that inspection can be performed in a high-temperature state and a low-temperature state.

As the heating and cooling mechanism, known appropriate heaters and coolers can be employed. For example, one with a double layer structure that includes a heating layer with a planar heater and a cooling layer provided with a passage for a cooling fluid, and one with a single layer structure in which a cooling pipe around which a heating heater is wound is embedded in a thermal conductor are non-limiting examples. Apart from electric heating, one in which a thermal fluid is circulated is also possible. Peltier elements may also be used.

### Alignment Apparatus

As illustrated in FIG. 3 and FIG. 4, the measurement unit 12 includes the alignment apparatus 70. The alignment apparatus 70 detachably supports the wafer chuck 50. The alignment apparatus 70 includes a Z-axis movement and rotation part 72, a probe position detection camera 82, a cleaning plate 84, a support table 74, an angle tilting mechanism 76, and an XY stage 78. The probe position detection camera 82 and the cleaning plate 84 are mounted on the Z-axis movement and rotation part 72. The support table 74 supports the Z-axis movement and rotation part 72. The angle tilting mechanism 76 supports the support table 74. The XY stage 78 supports the angle tilting mechanism 76.

The Z-axis movement and rotation part 72 moves an upper surface 72A in the Z-axis direction and rotates it about a central axis CL. The central axis CL is parallel to the Z axis. The upper surface 72A detachably supports the wafer chuck 50.

With this, the Z-axis movement and rotation part 72 moves the wafer chuck 50 in the Z-axis direction and rotates it about the central axis CL.

The probe position detection camera 82 captures an image of the probes 66 of the probe card 56. The image capture is performed at a position facing the probe card 56. Based on this image, the tip positions of the probes 66 can be detected.

Specifically, the XY coordinates of the tip positions of the probes 66 are detected from position coordinates (XY coordinates) in the image and the Z coordinates thereof are detected from the focal position of the probe position detection camera 82. The detection of the positions of the probes 66 is executed by a probe position detector 93 of a controller 90 (refer to FIG. 5).

The cleaning plate 84 removes shavings or dust such as foreign matter adhering to the tips of the probes 66. Removal of dust is performed with the probes 66 and the cleaning plate 84 being in contact with each other. By relatively moving, vibrating, or oscillating the two while they are in contact with each other, dust or the like at the tips of the probes 66 is removed by the cleaning plate 84.

The probe position detection camera 82 is integrally mounted on the Z-axis movement and rotation part 72 via a holding member 85. The cleaning plate 84 is mounted on the upper surface of a vertical stage 88. The vertical stage 88 is integrally mounted on the probe position detection camera 82 via a holding member 87. The vertical stage 88 moves the cleaning plate 84 in a direction parallel to the central axis CL.

However, the above is an example, and the probe position detection camera 82 and the cleaning plate 84 may be separately mounted on the Z-axis movement and rotation part 72. The probe position detection camera 82 and the cleaning plate 84 may be mounted on a member different from the Z-axis movement and rotation part 72.

The support table 74 is disposed on the lower surface side of the Z-axis movement and rotation part 72. That is, the Z-axis movement and rotation part 72 is supported on an upper surface 74A of the support table 74. On the upper surface 72A of the Z-axis movement and rotation part 72, the wafer chuck 50 is supported, and the probe position detection camera 82 is mounted via the holding member 85. Thus, when the support table 74 is tilted, the wafer chuck 50 and the probe position detection camera 82 are integrally tilted. Note that the support table 74 is tilted by the angle tilting mechanism 76.

Note that the support table 74 may directly or indirectly support the probe position detection camera 82. The support table 74 may be omitted, and the angle tilting mechanism described below may directly support the Z-axis movement and rotation part 72. The support table 74 is an example of a common support.

The angle tilting mechanism 76 is disposed between the support table 74 and the XY stage 78. The angle tilting mechanism 76 supports the support table 74 and tilts the support table 74.

The angle tilting mechanism 76 tilts the support table 74 to tilt the wafer chuck 50 and the probe position detection camera 82 integrally. This is achieved because both the wafer chuck 50 and the probe position detection camera 82 are supported on the support table 74 (the common support).

The angle tilting mechanism 76 is an example of a tilting mechanism.

The angle tilting mechanism 76 has the function of changing the tilt angle of the support table 74 with respect to a horizontal plane (an XY plane) as desired. For example, the following configuration can be preferably employed, although this is not limiting.

As an example, the angle tilting mechanism 76 includes three raising and lowering support members supporting the lower surface of the support table 74 at three points. When each raising and lowering support member is raised or lowered, the heights of the respective support points of the support table 74 can be mutually changed. This enables the tilt angle of the support table 74 with respect to the horizontal plane to be changed as desired.

Note that the above is an example, and the angle tilting mechanism 76 is not limited to such a configuration but can employ any known configuration as appropriate.

The XY stage 78 supports the angle tilting mechanism 76. The XY stage 78 also moves the Z-axis movement and rotation part 72 in XY directions. As a result, the wafer chuck 50 moves in the XY directions. This is because the wafer chuck 50 is detachably supported on the Z-axis movement and rotation part 72.

Note that the XY directions are directions parallel to the holding surface 50A of the wafer chuck 50. Moving the wafer chuck 50 in the XY directions is to relatively move the position of the wafer chuck 50 with respect to the probe card 56.

The XY stage 78 moves the alignment apparatus 70 between the measurement parts 16 on the same level (tier). The XY stage 78 includes a guide rail, a drive mechanism, and a transport pallet. The transport pallet moves on the guide rail by the drive mechanism. The XY stage 78 is provided for each level of the measurement unit 12. Note that the illustration of each element (the guide rail and the like) constituting the XY stage 78 is omitted.

The XY stage 78 may include a base, a Y-moving stage, and an X-moving stage. The base is placed on the transport pallet. The Y-moving stage is placed on the base and is movable in the Y-axis direction. The X-moving stage is placed on the Y-moving stage and is movable in the X-axis direction. The XY stage 78 is an example of a moving mechanism.

The alignment apparatus 70 includes the Z-axis movement and rotation part 72 and the XY stage 78. The Z-axis movement and rotation part 72 detachably supports the wafer chuck 50. The XY stage 78 supports the Z-axis movement and rotation part 72.

These makes the wafer chuck 50 movable in the X-axis direction, the Y-axis direction, and the Z-axis direction and rotatable in the θ direction. Relative alignment of the wafer chuck 50 with respect to the probe card 56 is performed by the alignment apparatus 70. The configuration of the alignment apparatus 70 described above is an example of an alignment apparatus.

Although illustration is omitted, the alignment apparatus 70 includes a wafer alignment camera. The wafer alignment camera is held at a side position of the Z-axis movement and rotation part 72 and above the wafer chuck 50 (that is, the wafer W) in the Z-axis direction.

The wafer alignment camera captures an image of the wafer W. Based on this image captured by the wafer alignment camera, the positions of the electrode pads of the semiconductor chips on the wafer W to be inspected are detected.

### Controller

FIG. 5 is a functional block diagram of the controller 90 of the prober 10. FIG. 5 illustrates a configuration related to the operation of the alignment apparatus 70 and omits the illustration of configurations related to other control.

The controller 90 illustrated in FIG. 5 includes an arithmetic circuit including various processors and memories. Various processors include central processing units (CPUs), graphics processing units (GPUs), application specific integrated circuits (ASICs), and programmable logic devices [for example, simple programmable logic devices (SPLDs), complex programmable logic devices (CPLDs), and field programmable gate arrays (FPGAs)]. The various functions of the controller 90 may be implemented by a single processor or implemented by a plurality of processors of the same type or different types.

This controller 90 is connected to the Z-axis movement and rotation part 72, the angle tilting mechanism 76, the XY stage 78, the probe position detection camera, and the like previously described via various communication interfaces (not illustrated).

The controller 90 includes a central controller 91, a movement controller 92, the probe position detector 93, a tilt angle detector 94, and the like. The central controller 91, the movement controller 92, the probe position detector 93, and the tilt angle detector 94 exhibit their respective functions by executing a non-illustrated control program, read from the memory or the like.

The central controller 91 manages the control of the movement controller 92, the probe position detector 93, the tilt angle detector 94, and the like. That is, the central controller 91 manages the overall operation of the controller 90. The central controller 91 receives operator instructions from the operating panel 21.

The probe position detector 93 detects the tip positions of the probes 66 based on the image captured by the probe position detection camera 82 and the focal position of the probe position detection camera 82. The XY coordinates are detected from the image and the Z coordinates are detected from the focal position.

The detection of the tip positions of the probes 66 by the probe position detector 93 is executed when the wafer W is inspected in the measurement part 16 to which the alignment apparatus 70 has been moved among the measurement parts 16. Information on the tip positions of the probes 66 detected by the probe position detector 93 is output to the movement controller 92. The information on the tip positions of the probes 66 may be stored in a memory or the like, not shown.

The tilt angle detector 94 detects the tilt angle of the probe card 56 based on the information on the tip positions of the probes 66 detected by the probe position detector 93. A virtual plane passing through the tip positions of the probes 66 is parallel to the probe card 56. If the virtual plane is referred to as “probe virtual plane,” the probe virtual plane is parallel to the body of the probe card holding the probes 66.

The tilt angle detector 94 detects the tilt angle of the probe card 56 by calculating the tilt angle of the probe virtual plane. The probe virtual plane can be calculated from the information on the tip positions of the probes 66 (that is, the XYZ coordinates of the tips of the probes 66) detected by the probe position detector 93.

Note that the tilt angle of the probe card 56 (or the probe virtual plane) refers to a tilt angle with respect to the horizontal plane (the XY plane).

The tilt angle detector 94 is an example of a detector.

The movement controller 92 controls the movement of the Z-axis movement and rotation part 72, the angle tilting mechanism 76, and the XY stage 78 by driving a non-illustrated drive mechanism.

The movement controller 92 acquires the position information of the electrode pads of the wafer W based on the image of the wafer W input from the wafer alignment camera.

The movement controller 92 also acquires the tip position information of the probes 66 acquired from the probe position detector 93.

The movement controller 92 further controls the movement of the Z-axis movement and rotation part 72 and the XY stage 78 based on both the position information of the electrode pads and the probes 66 to relatively move the wafer chuck 50 (the wafer W) with respect to the probe card 56. This allows relative alignment between the probes 66 and the electrode pads of the wafer W.

The movement controller 92 controls the angle tilting mechanism 76 such that the holding surface 50A of the wafer chuck 50 is parallel to the probe card 56 based on the detection result of the tilt angle detector 94 (the tilt angle of the probe card 56). That is, upon determining that the probe card 56 is “tilted” with respect to the horizontal plane (the XY plane), the movement controller 92 controls the angle tilting mechanism 76 in accordance with the tilt angle of the probe card 56 to tilt the wafer chuck 50 and the probe position detection camera 82 integrally such that the holding surface 50A of the wafer chuck 50 is parallel to the probe card 56. On the other hand, if the movement controller 92 determines that the probe card 56 is “not tilted” with respect to the horizontal plane, the angle tilting mechanism 76 tilts neither the wafer chuck 50 nor the probe position detection camera 82.

The movement controller 92 is an example of a controller configured to control the tilting mechanism.

### Probe Inspection Method

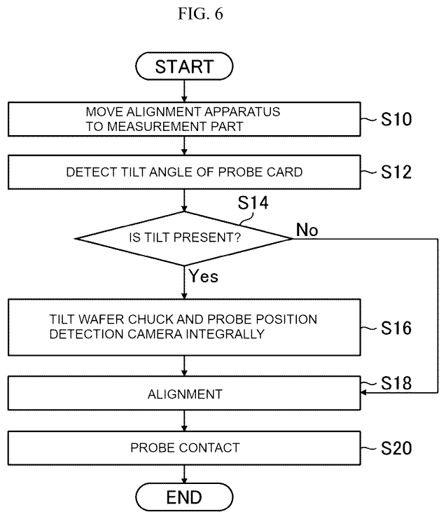

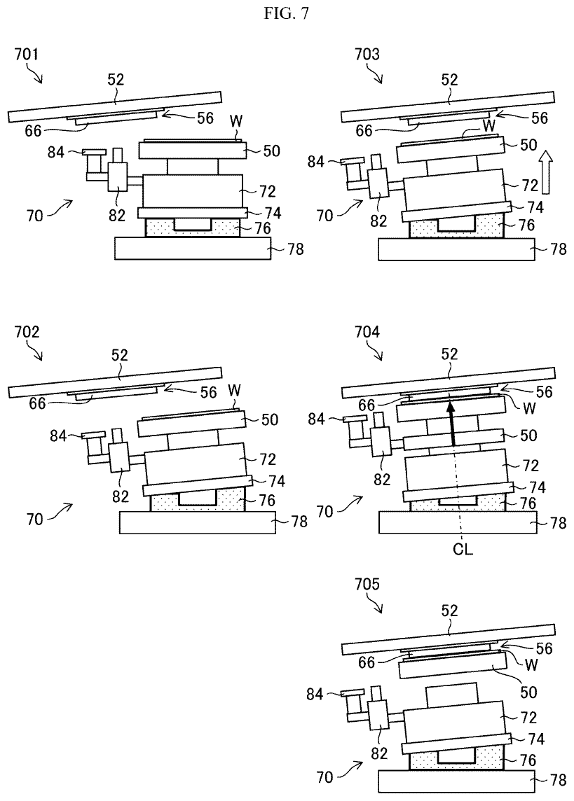

Next, a probe inspection method using the prober 10 of the embodiment will be described. FIG. 6 is a flowchart of a procedure of the probe inspection method. FIG. 7 is a diagram for illustrating the probe inspection method.

As illustrated in FIG. 6, first, the alignment apparatus 70 is moved to a certain measurement part 16 (Step S10). In the measurement part 16 as a movement destination, the wafer chuck 50 is supported on the Z-axis movement and rotation part 72 of the alignment apparatus 70. Then the loader 14 supplies the wafer W to the wafer chuck 50. With this, the wafer W is held on the holding surface 50A of the wafer chuck 50.

Next, the tilt angle of the probe card 56 is detected (Step S12). Specifically, the tilt angle of the probe card 56 is detected based on the information on the tip positions of the probes 66. The tip positions of the probes 66 are detected by the probe position detector 93. The detection of the tilt angle of the probe card 56 is performed by the tilt angle detector 94.

As illustrated in 701 in FIG. 7, the tip positions of the probes 66 are detected from the image captured by the probe position detection camera 82 and the focal position of the probe position detection camera 82. The tip positions of the probes 66 are detected while changing the relative position (the relative position in the XY directions) between the probe position detection camera 82 and the probe card 56. The relative position between the probe position detection camera 82 and the probe card 56 is adjusted by the XY stage 78 and the Z-axis movement and rotation part 72. The XY stage 78 and the Z-axis movement and rotation part 72 are controlled by the movement controller 92.

Note that FIG. 7 is a schematic view for illustration, and the tilt angles of the probe card 56 and the angle tilting mechanism 76 may be exaggerated from the actual angles to facilitate understanding of the inspection method. The figure does not necessarily illustrate the actual tilt angles.

Next, based on the tilt angle of the probe card 56 detected in Step S12, the presence or absence of the tilt of the probe card 56 is determined (Step S14). The determination is made by the movement controller 92. Specifically, based on the detection result of the tilt angle detector 94, it is determined whether the probe card 56 is tilted with respect to the horizontal plane (the XY plane). In other words, the presence or absence of the tilt of the probe card 56 is determined.

In Step S14, if the probe card 56 is tilted with respect to the horizontal plane as illustrated in 701 in FIG. 7, the movement controller 92 determines that “tilt is present” (Step S14: Yes), and the process proceeds to Step S16. On the other hand, if the probe card 56 is not tilted with respect to the horizontal direction in Step S14, the movement controller 92 determines that “tilt is absent” (Step S14: No), and the process proceeds to Step S18. Step S14 is an example of a detection step.

If it is determined to be Yes in Step S14, the wafer chuck 50 and the probe position detection camera 82 are integrally tilted (Step S16).

That is, when the probe card 56 is tilted with respect to the horizontal direction as illustrated in 701 in FIG. 7, the tilt of the wafer chuck 50 and the probe position detection camera 82 is integrally adjusted such that the holding surface 50A of the wafer chuck 50 is parallel to the probe card 56.

The adjustment of the tilt is made by the angle tilting mechanism 76. The angle tilting mechanism 76 is controlled by the movement controller 92 based on the detection result of the tilt angle detector 94.

This can make the probe card 56 and the wafer W parallel to each other as illustrated in 702 in FIG. 7. Step S16 is an example of a tilt control step.

Next, relative alignment between the wafer W and the probe card 56 is performed (Step S18). The alignment is performed under the control of the controller 90.

The probe position detection camera 82 captures an image of the tips of the probes 66. The probe position detector 93 detects the information on the tip positions of the probes 66 from the image captured by the probe position detection camera 82 and the focal position of the probe position detection camera 82.

Based on the image captured by the wafer alignment camera, the positions of the electrode pads of the semiconductor chips on the wafer W are detected.

As illustrated in 702 in FIG. 7, the optical axis of the probe position detection camera 82, which is perpendicular to the upper surface of the wafer chuck 50, is perpendicular to the lower surface of the probe card 56. This is because in Step 16, the angle tilting mechanism 76 tilted the wafer chuck 50 and the probe position detection camera 82 integrally such that the probe card 56 and the upper surface of the wafer chuck 50 are parallel to each other in accordance with the tilt angle of the probe card 56.

The probe position detection camera 82 can capture an image of the tips of the probes 66 from the front of the probe card 56, and thus the tips of the probes 66 can be detected with high accuracy. This also improves the accuracy of alignment.

Next, the movement controller 92 performs relative alignment between the wafer W and the probe card 56. The alignment is performed by driving the XY stage 78 and the Z-axis movement and rotation part 72. The alignment is performed based on the image acquired by the probe position detection camera 82, the focal position, and a result (position information) detected from the image of the wafer alignment camera.

Note that when the relative alignment is performed, a correction according to the tilt angle of the probe card 56 is applied to the calculation of the drive amount of each part.

Each part means, namely, the XY stage 78 and the Z-axis movement and rotation part 72. The drive amount means the amount of movement in the XYZ directions and the amount of rotation in the θ direction.

The tilt angle of the probe card 56 is detected by the tilt angle detector 94.

The tilt angle of the probe card 56 is equal to the tilt angle of the wafer chuck 50 tilted by the angle tilting mechanism 76.

Since the method for calculating the correction amount is known, the details thereof are omitted here.

After the relative alignment between the wafer W held on the wafer chuck 50 and the probe card 56 is performed, the wafer chuck 50 is moved toward the probe card 56. The Z-axis movement and rotation part 72 of the alignment apparatus 70 is controlled by the movement controller 92, and the wafer chuck 50 moves. The direction of movement is illustrated by the white arrow in 703 in FIG. 7. The white arrow is schematic, not reflecting the tilt of the probe card 56 and the Z-axis movement and rotation part 72.

When the wafer chuck 50 moves with a certain amount, a contact state is achieved in which each probe 66 of the probe card 56 and the electrode pad of each semiconductor chip of the wafer W are in contact with each other (Step S20). This state is illustrated in 704 in FIG. 7.

As illustrated by the bold arrow in 704 in FIG. 7, contact in which each probe 66 is squarely pressed against the electrode pad on the wafer W is possible. This is because the probe card 56 and the wafer chuck 50 were adjusted to be parallel to each other in Step 16.

This enables the contact of each probe 66 against the wafer W evenly and with high accuracy regardless of whether the probe card 56 is tilted with respect to the horizontal direction (the XY directions).

After the contact is made, the wafer chuck 50 is held by suction on the probe card 56 through vacuum suction or the like.

A ring-shaped sealing member is formed on the holding surface 50A of the wafer chuck 50. Thus, by depressurizing the space surrounded by the probe card 56 (or the head stage 52), the wafer chuck 50, and the sealing member by a sucker, the wafer chuck 50 is held by suction on the probe card 56.

After the wafer chuck 50 is held by suction on the probe card 56, the fixation between the wafer chuck 50 and the Z-axis movement and rotation part 72 is released. Then the Z-axis movement and rotation part 72 lowers as illustrated in 705 in FIG. 7. After that, wafer level inspection is performed.

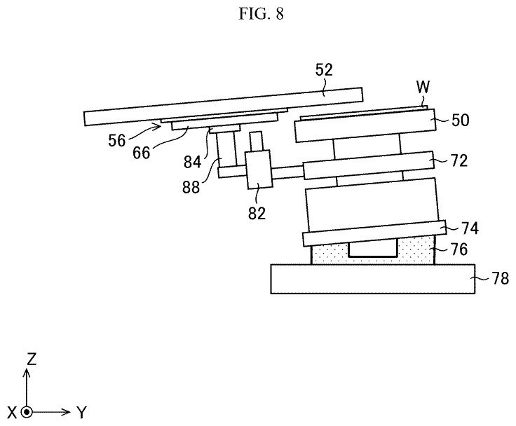

Next, a method for performing cleaning processing on the probes 66 using the cleaning plate 84 in the prober 10 will be described based on FIG. 8.

The cleaning processing is performed by relatively moving the cleaning plate 84 with respect to the probe card 56. The movement of the cleaning plate 84 is performed under the control of the movement controller 92. The cleaning plate 84 can be moved by controlling the Z-axis movement and rotation part 72 and the XY stage 78. The above control is performed based on the detection result of the probe position detection camera 82.

First, the cleaning plate 84 is moved with respect to the probe card 56 by the Z-axis movement and rotation part 72, the XY stage 78, and the vertical stage 88 supporting the cleaning plate 84 to bring the cleaning plate 84 into contact with the lower surface of the probe card 56. Subsequently, the cleaning processing on each probe 66 is performed by relatively moving the cleaning plate 84 with respect to the probe card 56.

As illustrated in FIG. 8, the cleaning processing is performed with the probe card 56 and the cleaning plate 84 being parallel to each other. This is because the angle tilting mechanism 76 also tilts the cleaning plate 84 integrally with the wafer chuck 50 and the like.

This can inhibit one-sided wear of the cleaning plate 84. As a result, the frequency of replacing the cleaning plate 84 can be reduced, and running costs can be reduced.

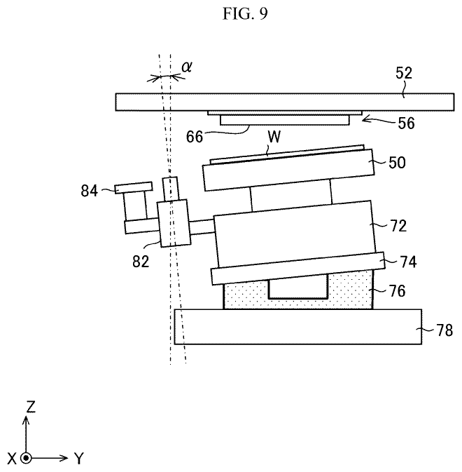

The angle tilting mechanism 76 can also be used for cases apart from adjusting the parallelism between the probe card 56 and the wafer chuck 50. FIG. 9 is a diagram of another use of the angle tilting mechanism 76.

In FIG. 9, the probe card 56 is not tilted with respect to the horizontal plane.

Meanwhile, the wafer chuck 50 is adjusted to be non-parallel to the probe card 56 by the angle tilting mechanism 76. This causes also the probe position detection camera 82 to be integrally tilted. In the case in FIG. 9, the tilt angle of the optical axis of the probe position detection camera 82 makes an angle α with respect to the Z axis.

When the optical axis of the probe position detection camera 82 is tilted with respect to the Z-axis direction, the range of the XY plane that can be observed by the probe position detection camera 82 can be expanded.

This enables easy detection of, for example, the probe card 56 with a large diameter exceeding 300 mm or positioning marks around the probe card 56.

### Modification

The embodiment described above described the fact that the tilt angle of the probe card 56 is detected based on the information on the tip positions of the probes 66. The above is a non-limiting example of detection of the tilt angle of the probe card. The following is another example of a method for detecting the tilt angle of the probe card 56.

First, respective distance sensors are disposed at a plurality of positions different from each other on the holding surface 50A of the wafer chuck 50. Next, a relative distance to the probe card 56 is measured using the distance sensors disposed at the respective positions. From the measurement result, the tilt angle of the probe card 56 can be calculated.

The embodiment described above described a case in which the prober 10 is a multistage type prober including the measurement parts 16. However, the present disclosure is also applicable to probers including only one measurement part.

The embodiments of the prober have been described in detail, but the present disclosure may of course be subject to some improvements or modifications to the extent that they do not depart from the gist of the present disclosure.

### Reference Signs List

10 PROBER
11 CASING
12 MEASUREMENT UNIT
13 FRAME
14 LOADER
16 MEASUREMENT PART
18 LOAD PORT
20 WAFER CASSETTE
21 OPERATING PANEL
22 TRANSPORT UNIT
24 TRANSPORT ARM
50 WAFER CHUCK
50A HOLDING SURFACE
52 HEAD STAGE
54 TEST HEAD
56 PROBE CARD
66 PROBE
70 ALIGNMENT APPARATUS
72 Z-AXIS MOVEMENT AND ROTATION PART
72A UPPER SURFACE
74 SUPPORT TABLE
74A UPPER SURFACE
76 ANGLE TILTING MECHANISM
78 XY STAGE
82 PROBE POSITION DETECTION CAMERA
84 CLEANING PLATE
85 HOLDING MEMBER
87 HOLDING MEMBER
88 VERTICAL STAGE
90 CONTROLLER
91 CENTRAL CONTROLLER
92 MOVEMENT CONTROLLER
93 PROBE POSITION DETECTOR
94 TILT ANGLE DETECTOR
CL CENTRAL AXIS
W WAFER
α ANGLE

1. A prober comprising:
a plurality of measurement parts, each of the measurement parts being provided with a wafer chuck and a probe card, the wafer chuck having a holding surface configured to hold a wafer, the probe card having a plurality of probes on a surface facing the holding surface; and
an alignment apparatus configured to be movable between the measurement parts and detachably support the wafer chuck at a measurement part as a movement destination to perform relative alignment of the wafer chuck with respect to the probe card, wherein
the alignment apparatus includes:
a probe position detection camera configured to detect tip positions of the probes at a position facing the probe card; and
a tilting mechanism configured to tilt the wafer chuck and the probe position detection camera integrally.

2. The prober according to claim 1, wherein
the alignment apparatus includes a common support configured to commonly support the wafer chuck and the probe position detection camera, and
the tilting mechanism tilts the common support to tilt the wafer chuck and the probe position detection camera integrally.

3. The prober according to claim 2, wherein
the alignment apparatus includes a moving mechanism configured to relatively move the wafer chuck with respect to the probe card in a direction parallel to the holding surface, and
the tilting mechanism is provided between the moving mechanism and the common support.

4. The prober according to claim 1, further comprising:
a detector configured to detect a tilt angle of the probe card; and
a controller configured to control the tilting mechanism such that the holding surface is parallel to the probe card based on a detection result of the detector.

5. The prober according to claim 4, wherein the detector detects the tilt angle of the probe card based on a detection result of the probe position detection camera.

6. The prober according to claim 1, wherein
the alignment apparatus includes a cleaning plate configured to clean tips of the probes, and
the tilting mechanism tilts the cleaning plate integrally with the wafer chuck.

7. A probe inspection method in a prober including:
a probe card including a plurality of measurement parts, each of the measurement parts having a wafer chuck having a holding surface configured to hold a wafer and a plurality of probes on a surface facing the holding surface; and
an alignment apparatus configured to be movable between the measurement parts and detachably support the wafer chuck at a measurement part as a movement destination to perform relative alignment of the wafer chuck with respect to the probe card, wherein
the alignment apparatus includes a probe position detection camera configured to detect tip positions of the probes at a position facing the probe card, and a tilting mechanism configured to tilt the wafer chuck, the probe inspection method comprising:
a detection step of detecting a tilt angle of the probe card; and
a tilt control step of controlling the tilting mechanism based on a detection result of the detection step to tilt the wafer chuck and the probe position detection camera integrally such that the holding surface is parallel to the probe card.

8. The probe inspection method according to claim 7, wherein the detection step includes detecting a tilt angle of the probe card based on a detection result of the probe position detection camera.

9. The prober according to claim 2, further comprising:
a detector configured to detect a tilt angle of the probe card; and
a controller configured to control the tilting mechanism such that the holding surface is parallel to the probe card based on a detection result of the detector.

10. The prober according to claim 3, further comprising:
a detector configured to detect a tilt angle of the probe card; and
a controller configured to control the tilting mechanism such that the holding surface is parallel to the probe card based on a detection result of the detector.

11. The prober according to claim 2, wherein
the alignment apparatus includes a cleaning plate configured to clean tips of the probes, and
the tilting mechanism tilts the cleaning plate integrally with the wafer chuck.

12. The prober according to claim 3, wherein
the alignment apparatus includes a cleaning plate configured to clean tips of the probes, and
the tilting mechanism tilts the cleaning plate integrally with the wafer chuck.
